(19) United States
(12) Patent Application Publication
(10) Pub. No.: US 2025/0248190 A1
(43) Pub. Date: Jul. 31, 2025

(54) SEMICONDUCTOR DEVICE ARRANGEMENT AND METHOD OF MANUFACTURING THE SAME

(71) Applicant: EPISTAR CORPORATION, Hsinchu (TW)

(72) Inventors: Tai-Ni CHU, Hsinchu (TW); Wei-Shan HU, Hsinchu (TW); Ching-Tai CHENG, Hsinchu (TW)

(21) Appl. No.: 19/033,045

(22) Filed: Jan. 21, 2025

(30) Foreign Application Priority Data
Jan. 31, 2024 (TW) 113103732
Oct. 23, 2024 (TW) 113140299

(51) Int. Cl. H10H 29/02; H10H 29/85

(52) U.S. Cl. CPC H10H 29/02; H10H 29/857

(57) ABSTRACT

A semiconductor device arrangement includes a carrier, a semiconductor device located on the carrier and an adhesive portion between the carrier and the semiconductor device. The semiconductor device includes a semiconductor stack, a first electrode, a second electrode, a first electrical connection and a second electrical connection. The first electrode is located between the semiconductor stack and the first electrical connection, and both of the first electrical connection and the second electrical connection are arranged to face the carrier. The adhesive portion includes a first protruding portion and a second protruding portion. The first protruding portion and the second protruding portion are respectively connected with the first electrical connection and the second electrical connection. The uppermost surfaces of the first electrical connection and the second electrical connection are located at different elevations, and at least one of the first and second electrical connections is located below the semiconductor stack.

### CROSS-REFERENCE TO RELATED APPLICATIONS

This application claims priority to, and the benefit of, Taiwan Patent Application Number 113103732 filed on Jan. 31, 2024, and Taiwan Patent Application Number 113140299 filed on Oct. 23, 2024, the entireties of which are hereby incorporated by reference.

### TECHNICAL FIELD

The present disclosure relates to a semiconductor device arrangement, and, in particular, to a semiconductor device arrangement in which a plurality of semiconductor devices is arranged on a carrier, and the method of manufacturing the same.

### DESCRIPTION OF BACKGROUND ART

The light-emitting diode (LED) is a semiconductor device which has many advantages, such as low power consumption, low heat generation, long operating life, high impact resistance, small size, fast reaction speed, and stable luminescence wavelength. Therefore, it is widely used in many fields such as household appliances, equipment indicators, and display devices.

In order to manufacture different electronic devices, multiple LEDs need to be transferred to different substrates. The manufacturing method usually include transferring a plurality of LEDs from a growth substrate to a temporary substrate and adhering the plurality of LEDs to the temporary substrate through an adhesive layer on the temporary substrate. Next, the adhesion between the LED and the adhesive layer is reduced by irradiation or heating. Then, a pick-and-place step is performed using a pickup device to transfer the selected LEDs from the temporary substrate to a target substrate.

In order to reduce the adhesion between the LED and the adhesive layer, the adhesive layer is fully irradiated or heated. When irradiation or heating is insufficient, the adhesive layer tends to remain on the LED even though the selected LED can be transferred from the temporary substrate to the target substrate. When the adhesive layer remains on an electrode of the LED, the electrical connection between the LED and the target substrate will be reduced.

### SUMMARY

In one embodiment, a semiconductor device arrangement is provided. The semiconductor device arrangement includes a carrier, a plurality of semiconductor devices, and a plurality of adhesive portions. The plurality of semiconductor devices is located on the carrier and separated from each other, wherein one of the plurality of semiconductor devices includes a semiconductor stack, a first electrode, a second electrode, a first electrical connection, and a second electrical connection. The first electrode is located between the semiconductor stack and the first electrical connection, and the first electrical connection and the second electrical connection are arranged to face the carrier. The plurality of adhesive portions is located between the plurality of semiconductor devices and the carrier, wherein one of the plurality of adhesive portions includes a first protruding portion and a second protruding portion. The first protruding portion connects the first electrical connection, and the second protruding portion connects the second electrical connection. The first electrical connection and the second electrical connection have uppermost surfaces located at different elevations, and at least one of the first electrical connection and the second electrical connection is located below the semiconductor stack.

In one embodiment, a method of manufacturing a semiconductor device arrangement is provided. The method includes: providing a first support substrate and a plurality of semiconductor devices located on the first support substrate and separated from each other; providing a second support substrate including a carrier and an adhesive layer located on the carrier, wherein the adhesive layer is cured and has a glass transition temperature; and heating the adhesive layer to a first temperature and making the adhesive layer to contact the plurality of semiconductor devices, wherein the first temperature and the glass transition temperature satisfy an equation:

$$0 < \frac{{T}_{1} - {T}_{g}}{{T}_{g}} \leq 70 \%$$

wherein T₁ is the first temperature, and T_{g} is the glass transition temperature.

### BRIEF DESCRIPTION OF THE DRAWINGS

The embodiments of the present disclosure can be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1 illustrates a top view of a semiconductor device arrangement and an enlarged view of RI region in accordance with one embodiment of the present disclosure.

FIGS. 2A and 2B illustrate a cross-sectional view along line AA′ in FIG. 1.

FIG. 3 illustrates an enlarged view of regions R21 and R22 in FIG. 2A.

FIG. 4 illustrates a top view of a semiconductor device in accordance with one embodiment.

FIG. 5 illustrates a cross-sectional view of a plurality of semiconductor device adhered on a second support substrate in different steps.

FIG. 6 illustrates a cross-sectional view of a step of separating the semiconductor device from the first support substrate in accordance with one embodiment.

FIG. 7 illustrates a cross-sectional view of a patterned adhesive layer in accordance with one embodiment.

FIG. 8 illustrates a cross-sectional view of a step of forming an adhesive portion in accordance with one embodiment.

FIG. 9 illustrates a cross-sectional view of a step of using a pickup device to separate a semiconductor device from a second support substrate in accordance with one embodiment.

FIG. 10 illustrates a cross-sectional view of a semiconductor device arrangement in accordance with one embodiment.

FIG. 11 illustrates a cross-sectional view of a plurality of vertical semiconductor devices adhered on a second support substrate in different steps.

FIG. 12 illustrates a cross-sectional view of a step of separating the vertical semiconductor device from the first support substrate.

FIG. 13 illustrates a cross-sectional view of a step of forming an adhesive portion beneath a vertical semiconductor device in accordance with one embodiment.

FIG. 14 illustrates a cross-sectional view of a step of using a pickup device to separate a vertical semiconductor device from a second support substrate in accordance with one embodiment.

### DETAILED DESCRIPTION OF THE APPLICATION

The embodiments of the present disclosure will be described in detail below with reference to the accompanying drawings, so that those skilled in the art to which the present disclosure belongs can fully understand the spirit of the present disclosure. The present disclosure is not limited to the following embodiments, but may be implemented in other forms. In this specification, there are some same reference numerals, indicating components with the same or similar structure, function and principle. For simplicity of description, components with the same reference numerals will not be described again.

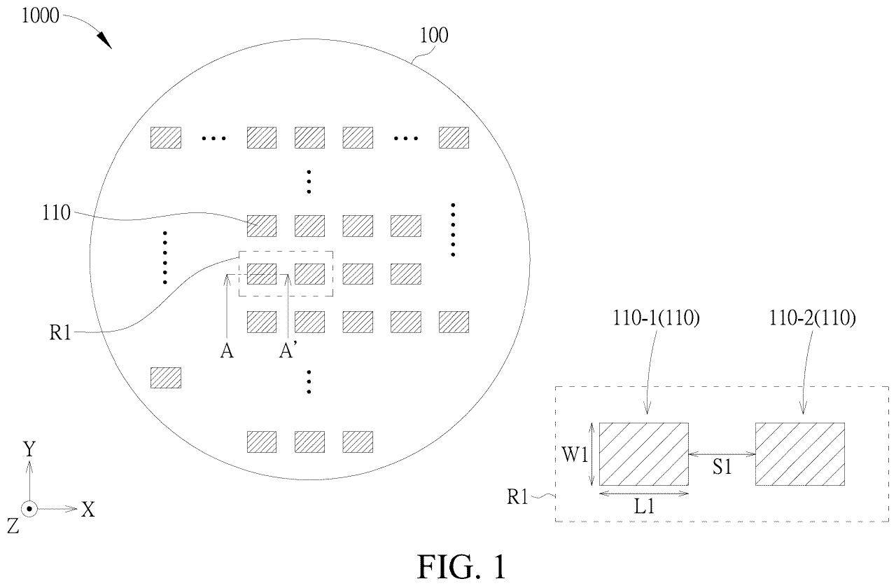

FIG. 1 illustrates a top view of a semiconductor device arrangement and an enlarged view of RI region in accordance with one embodiment of the present disclosure. As shown in FIG. 1, a semiconductor device arrangement 1000 includes a carrier 100 and a plurality of semiconductor devices 110 arranged on the carrier 100. The plurality of semiconductor devices 110 is located on the carrier 100 and separated from each other, and is arranged in a regular or irregular arrangement pattern. The regular arrangement pattern includes a triangle, a rectangle, a circle, a hexagon, and an octagon. The irregular arrangement pattern includes a regular pattern with random gaps, a scalene polygon, and an unequal polygon. An adhesive portion (not shown) is provided between the carrier 100 and the plurality of semiconductor devices 110 so that the plurality of semiconductor devices 110 can be attached to the carrier 100 through the adhesive portion on the carrier 100. The adhesive portion is distributed intermittently or continuously on the surface of the carrier 100.

In one embodiment, the carrier 100 is used to support the semiconductor devices 110, so the carrier 100 can also be used as a support substrate. In one embodiment, the carrier 100 is a non-epitaxial material or a non-growth substrate, such as a ceramic substrate, a metal substrate, a glass substrate, a quartz substrate, a thermal release tape, a UV release tape, a chemical release tape, a heat-resistant tape, a blue tape, or a tape with a dynamic release layer (DRL).

The semiconductor device 110 is a transistor or a LED, and the plurality of semiconductor devices 110 have the same or similar structure and size. In one embodiment, the projected area of the semiconductor device 110 in Z direction is in the range of 1 μm² to 10,000 μm². The shortest distance between two adjacent semiconductor devices 110 in the same column or row is in the range of 1 μm to 50 μm.

As shown in the enlarged view of RI region in FIG. 1, two adjacent semiconductor devices 110, such as a first semiconductor device 110-1 and a second semiconductor device 110-2, both have a maximum length L1 (or called length) and a maximum width W1 (or called width). The maximum length L1 is greater than or equal to the maximum width W1, the maximum length L1 is between 1 μm and 100 μm, and the maximum width W1 is between 1 μm and 100 μm. The shortest distance SI between the first semiconductor device 110-1 and the second semiconductor device 110-2 will be smaller than the maximum width W1. In one embodiment, the shortest distance SI is between 1 μm and 10 μm.

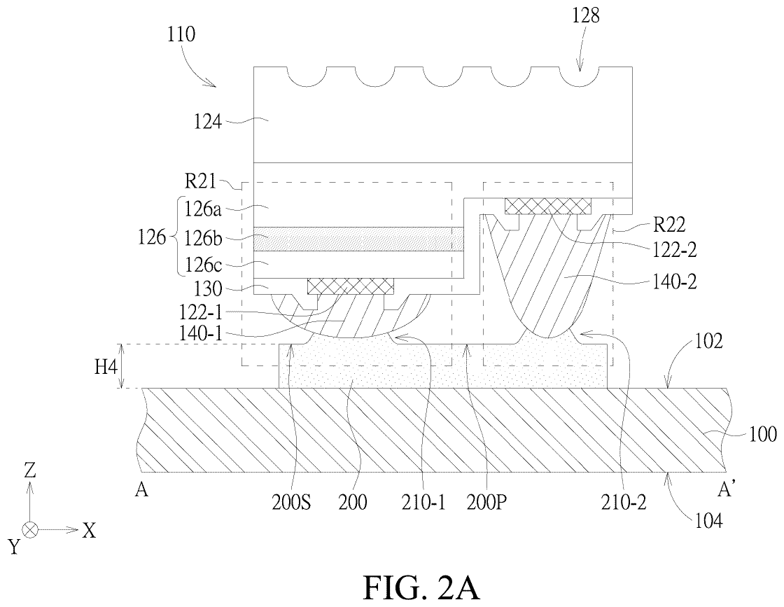

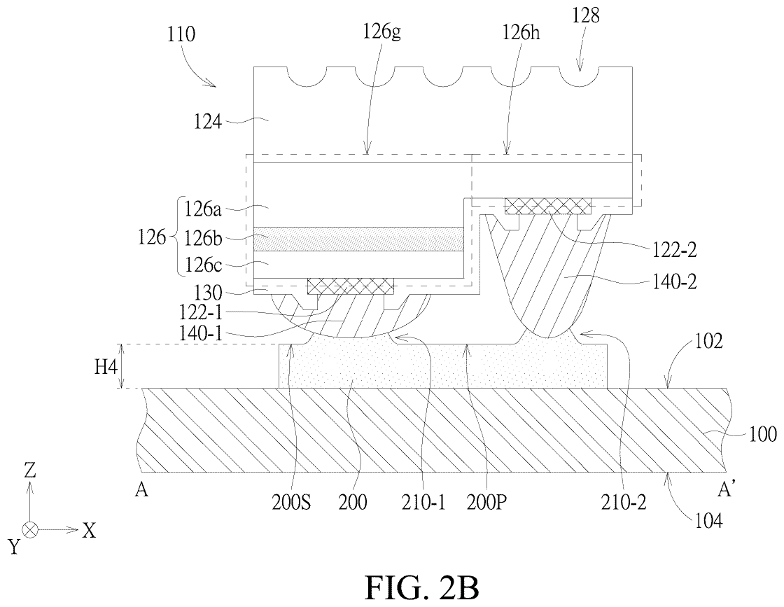

FIGS. 2A and 2B illustrate a cross-sectional view along line AA′ in FIG. 1. As shown in FIG. 2A, the carrier 100 has a front surface 102 and a rear surface 104 opposite the front surface 102, and the semiconductor devices 110 and the adhesive portion 200 are arranged on the front surface 102 of the carrier 100.

As shown in FIG. 2A, in one embodiment, the semiconductor device 110 is a LED and includes a semiconductor stack 126, a first electrode 122-1, a second electrode 122-2, a first electrical connection 140-1, and a second electrical connection 140-2. The first electrode 122-1 is located between the semiconductor stack 126 and the first electrical connection 140-1, and the second electrode 122-2 is located between the semiconductor stack 126 and the second electrical connection 140-1. The first electrical connection 140-1 and the second electrical connection 140-2 are arranged to face the front surface 102 of the carrier 100. The semiconductor stack 126 includes a first semiconductor layer 126a, a second semiconductor layer 126c, and an active layer 126b located between the first semiconductor layer 126a and the second semiconductor layer 126c. In one embodiment, the semiconductor device 110 further includes a buffer layer 124 and an insulating layer 130. The buffer layer 124 and the carrier 100 are located on opposite sides of the semiconductor stack 126. In one embodiment, the buffer layer 124 is a semiconductor stack with superlattice structure. The insulating layer 130 has a portion located between the first electrical connection 140-1 and the semiconductor stack 126, and has another portion located between the second electrical connection 140-2 and the semiconductor stack 126. The insulating layer 130 has a plurality of openings to expose the first electrode 122-1 and the second electrode 122-2 respectively, thereby filling the first electrical connection 140-1 and the second electrical connection 140-2 into the openings to electrically connect the first electrode 122-1 and the second electrode 122-2 respectively.

In one embodiment, the buffer layer 124 includes a plurality of recessed regions 128 on the uppermost surface. If the buffer layer 124 and the semiconductor stack 126 are epitaxially grown on a patterned sapphire substrate (PSS) wherein the PSS has multiple protruding portions on the surface, a plurality of recessed regions 128 corresponding to the protruding portions is formed on the uppermost surface of the buffer layer 124 after the PSS is removed. The protruding portions on the surface of the PSS include cones or pyramids (hereinafter collectively referred to as cones). The height of the cone is in the range of 300 nm to 2 μm and the maximum width is in the range of 1 μm to 4 μm (in a top view, a side view or a cross-sectional view), so that each recessed region 128 located on the uppermost surface has a maximum width (diameter) between 1 μm and 4 μm, and a depth between 300 nm and 2 μm. The recessed region 128 can increase the luminous efficiency or luminous angle of the semiconductor device 110.

In one embodiment, the first semiconductor layer 126a and the second semiconductor layer 126c respectively include different dopants, such as n-type dopants and p-type dopants, so that the first semiconductor layer 126a and the second semiconductor layer 126c can provide electrons and holes respectively and recombine them in the active layer 126b to generate light. The active layer 126b includes multiple quantum well structures. As shown in FIG. 2B, the semiconductor stack 126 has a mesa area 126g and a non-mesa area 126h. The thickness of the mesa area is greater than the thickness of the non-mesa area. The mesa area includes the first semiconductor layer 126a, the active layer 126b, and the second semiconductor layer 126c. The non-mesa area includes the first semiconductor layer 126a, but does not include the active layer 126b and the second semiconductor layer 126c.

In one embodiment, the first electrode 122-1 locates on the mesa area, the second electrode 122-2 locates on the non-mesa area, the first electrode 122-1 is electrically connected to the second semiconductor layer 126c, and the second electrode 122-2 is electrically connected to the first semiconductor layer 126a. The first electrode 122-1 and the second electrode 122-2 each includes a single-layer or multi-layers metal structure, and includes chromium (Cr), nickel (Ni), titanium (T₁), platinum (Pt), palladium (Pd), silver (Ag), gold (Au), aluminum (Al), copper (Cu), or combination thereof.

In one embodiment, the first electrical connection 140-1 of the semiconductor device 110 is electrically connected to the first electrode 122-1, and the second electrical connection 140-2 of the semiconductor device 110 is electrically connected to the second electrode 122-2. As shown in FIG. 2A, at least one physical dimension of the first electrical connection 140-1 and the second electrical connection 140-2 is larger than that of the first electrode 122-1 and the second electrode 122-2, respectively, wherein the physical dimension includes length, width, and height. In one embodiment, the material of the first electrical connection 140-1 and the second electrical connection 140-2 includes tin (Sn) or silver (Ag), and can be the same as or different from that of the first electrode 122-1 and the second electrode 122-2.

The adhesive portion 200 is located between the semiconductor device 110 and the carrier 100. The material of the adhesive portion 200 includes cross-linked and cured polymers, such as polyimide (PI), polyepoxide (EPO, Epoxy), polybenzoxazole (PBO), polysiloxane, cyclic olefin polymer (COP), or benzocyclobutane (BCB). In one embodiment, the adhesive portion 200 includes a first protruding portion 210-1 and a second protruding portion 210-2. The first protruding portion 210-1 is directly connected to the first electrical connection 140-1 but not electrically connected thereto, and the second protruding portion 210-2 is directly connected to the second electrical connection 140-2 but not electrically connected thereto.

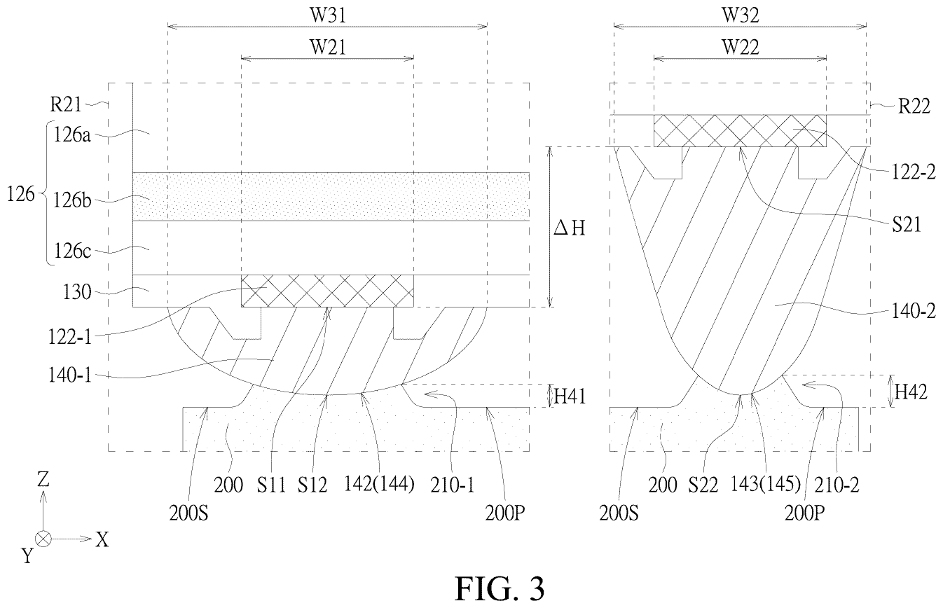

FIG. 3 illustrates an enlarged view of regions R21 and R22 in FIG. 2A. As shown in FIG. 3, the uppermost surface S11 of the first electrical connection 140-1 and the uppermost surface S21 of the second electrical connection 140-2 are located at different elevations with a height difference ΔH. The first electrical connection 140-1 has an outer surface 142 facing the adhesive portion 200, and the outer surface 142 can be a curved surface 144. The second electrical connection 140-2 has an outer surface 143 facing the adhesive portion 200, and the outer surface 143 can be a curved surface 145. In one embodiment, one or both of the outer surface 142 and the outer surface 143 can be a plane surface (the plane here refers to the macro view, not shown in the figure). In other words, one of the outer surfaces 142 and 143 can be a flat surface and the other one can be a curved surface, or both can be flat surfaces. The outer surfaces 142 and 143 (or the curved surfaces 144 and 145) can respectively contact the first protruding portion 210-1 and the second protruding portion 210-2, so that the semiconductor device 110 is attached to the adhesive portion 200 via the outer surfaces 142 and 143 of the electrical connections 140-1 and 140-2. In one embodiment, the contact surface of the electrical connections 140-1, 140-2 contacting the protruding portion is not limited to a curved surface, and can also be a flat surface. In one embodiment, the curved surface 144 has an endpoint S12 farthest from the uppermost surface S11, and the curved surface 145 has an endpoint S22 farthest from the uppermost surface S21. The endpoint S12 and the endpoint S22 can be located at substantially the same elevation. In another embodiment, the height difference between the endpoint S12 and the endpoint S22 is between 0.01*ΔH-0.1*ΔH, 0.1*ΔH-0.5*ΔH, or 0.5*ΔH-0.9*ΔH, for example, 0.1*ΔH. The first electrical connection 140-1 has a maximum width W31, and the second electrical connection 140-2 has a maximum width W32. The first electrode 122-1 has a maximum width W21, and the second electrode 122-2 has a maximum width W22. The maximum width W31 of the first electrical connection 140-1 is greater than the maximum width W21 of the first electrode 122-1, the maximum width W32 of the second electrical connection 140-2 is greater than the maximum width W22 of the second electrode 122-2.

As shown in FIG. 3, the adhesive portion 200 has an upper surface 200S. The upper surface 200S has a flat region 200P located in an area other than the first protruding portion 210-1 and the second protruding portion 210-2. In one embodiment, the flat region 200P is located on both sides of the first protruding portion 210-1, both sides of the second protruding portion 210-2, and/or between the first protruding portion 210-1 and the second protruding portion 210-2. In one embodiment, the first protruding portion 210-1 has a maximum height H41, and the second protruding portion 210-2 has a maximum height H42. In a cross-sectional view, the maximum height H41 is the height difference from the flat region 200P to the highest contact point between the first protruding portion 210-1 and the first electrical connection 140-1. Similar, the maximum height H42 is the height difference from the flat region 200P to the highest contact point between the second protruding portion 210-2 and the second electrical connection 140-2. The difference between the maximum height H41 and the maximum height H42 is less than 1 μm. As shown in FIG. 2A, the adhesive portion 200 has an average thickness H4. In one embodiment, H41/H4, H42/H4, or both is in the range of 1/10 to ½. By adjusting the heights of the first protruding portion 210-1 and the second protruding portion 210-2, the contact area between the first protruding portion 210-1 and the first electrical connection 140-1 and the contact area between the second protruding portion 210-2 and the second electrical connection 140-2 can be adjusted, thereby changing the adhesive force between the semiconductor device 110 and the adhesive portion 200. When the maximum heights H41 and H42 increase, the contact areas between the first protrusion portion 210-1 and the first electrical connection 140-1 and between the second protrusion 210-2 and the second electrical connection 140-2 decrease, thereby reducing the adhesion force between the semiconductor device 110 and the adhesion portion 200, and vice versa.

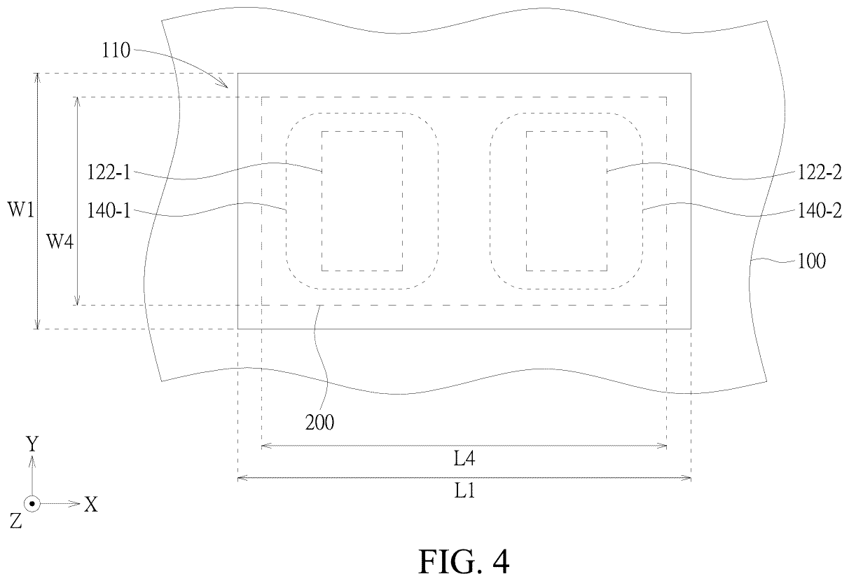

FIG. 4 illustrates a top view of a semiconductor device 110 according to an embodiment. As shown in FIG. 4, the semiconductor device 110 is located on the carrier 100 and has a maximum length L1 and a maximum width W1. The first electrode 122-1 corresponds to the first electrical connection 140-1, and the second electrode 122-2 corresponds to the second electrical connection 140-2. The projected contour of the first electrode 122-1 is smaller than the projected contour of the first electrical connection 140-1, and the projected contour of the second electrode 122-2 is smaller than the projected contour of the second electrical connection 140-2.

In one embodiment, the maximum length L4 of the adhesive portion 200 is smaller than the maximum length L1 of the semiconductor device 110, and the maximum width W4 of the adhesive portion 200 is smaller than the maximum width W1 of the semiconductor device 110. Therefore, as shown in FIG. 4, the adhesive portion 200 can be completely covered (or completely overlapped) by the corresponding semiconductor device 110 such that the outermost edge of the adhesive portion 200 does not exceed the outermost edge of the semiconductor device 110. In one embodiment, the projected area of the adhesive portion 200 in Z direction is in the range of 10 μm² to 10000 μm², smaller than the projected area of the corresponding semiconductor device 110 in Z direction.

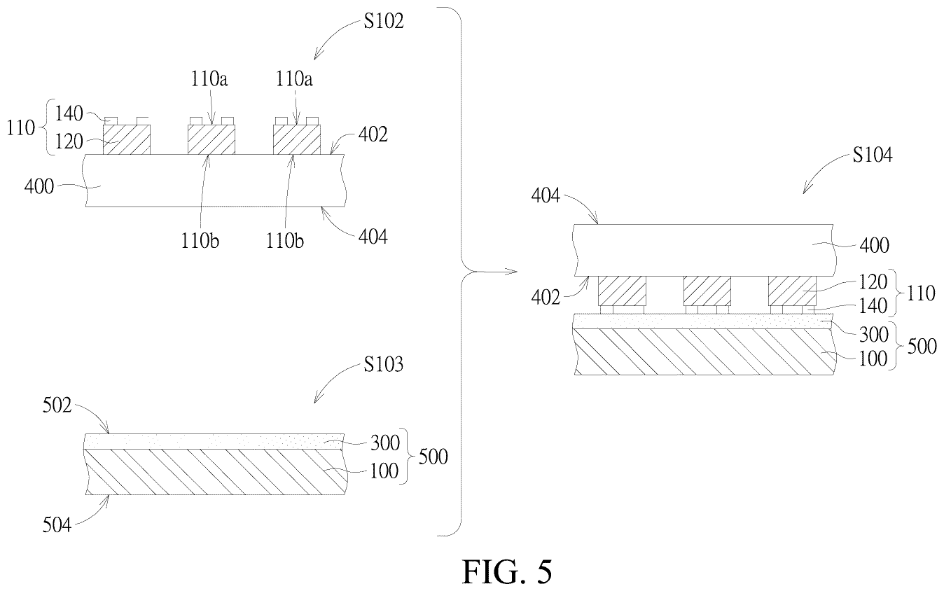

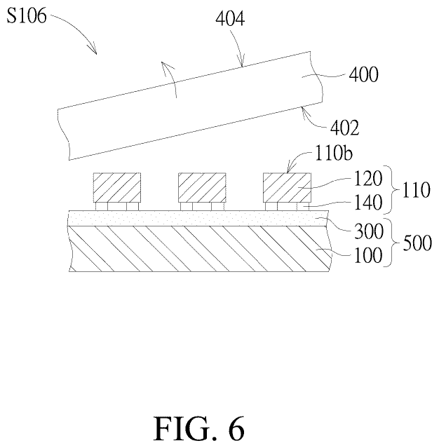

FIG. 5 illustrates a cross-sectional view of intermediate structures in a process of bonding a plurality of semiconductor devices 110 to a second support substrate 500 according to an embodiment. In one embodiment, the semiconductor device 110 is a transistor or a LED. FIG. 6 illustrates a cross-sectional view of an intermediate structure during a step of separating the first support substrate 400 and the semiconductor device 110 according to an embodiment. As shown in FIG. 5, in step S102, a first support substrate 400 and a plurality of semiconductor devices 110 are provided, and the plurality of semiconductor devices 110 is located on the front surface 402 of the first support substrate 400 and separated from each other. The semiconductor device 110 has a front surface 110a and a rear surface 110b. The front surface 110a is away from the first support substrate 400, and the rear surface 110b faces the first support substrate 400. In one embodiment, the semiconductor device 110 includes a body 120 and an electrical connection 140. The body 120 includes the semiconductor stack 126 as shown in FIG. 2A, and the electrical connection 140 includes the first electrical connection 140-1 and the second electrical connection 140-2 as shown in FIG. 2A.

In one embodiment, the first support substrate 400 is a growth substrate for epitaxial growth, wherein the semiconductor device 110 is formed on the growth substrate. The materials of the growth substrate include but are not limited to silicon (Si), germanium (Ge), lithium aluminate (LiAlO₂), zinc oxide (ZnO), silicon carbide (SiC), sapphire, gallium nitride (GaN), aluminum nitride (AlN), gallium arsenide (GaAs), indium phosphide (InP). In one embodiment, the first support substrate 400 includes a non-epitaxial material or a non-growth substrate. When the first support substrate 400 includes a non-epitaxial material or a non-growth substrate, a connection layer such as a polymer layer (not shown) can be located between the rear surface 110b of each semiconductor device 110 and the first support substrate 400 for temporarily fixing the semiconductor device 110 to the first support substrate 400.

In step S103, a second support substrate 500 is provided. The second support substrate 500 has a front side 502 and a back side 504 opposite to the front side 502, and includes the carrier 100 and a continuously adhesive layer 300. The adhesive layer 300 is located on the front surface 102 of the carrier 100, and the average thickness of the adhesive layer 300 is in the range of 0.05 μm to 5 μm. In one embodiment, the adhesive layer 300 is cured and includes a polymer, wherein the polymer has a glass transition temperature T_{g}. The glass transition temperature of the polymer is, for example, between 100° C. and 110° C. In one embodiment, the polymer includes polyimide (PI), polyepoxide (EPO), polybenzoxazole (PBO), polysiloxane, cyclic olefin polymer (COP), or benzocyclobutane (BCB). In one embodiment, the adhesive layer 300 can be formed by spin coating a liquid material on the front surface 102 of the carrier 100, and then baking it at a temperature To between 160° C. and 200° C. The liquid material forms the adhesive layer 300 that is non-fluid and has a cross-linked structure. In step S103, the adhesive layer 300 does not have any adhesiveness or only has slight adhesiveness. For example, when a flat metal with an area of 3*3 mm² comes into contact with the adhesive layer 300, the flat metal and the adhesive layer 300 can be separated with a pulling force of less than 1 gram. In one embodiment, the adhesive layer 300 is formed on the front surface 102 of the carrier 100 through dip coating, screen printing, doctor blade coating, or other manufacturing process.

Step S104 is performed after step S102 and step S103. The adhesive layer 300 is heated at a first temperature T₁, for example, in the range of 110° C. to 130° C., and at least one of the first support substrate 400 and the second support substrate 500 is moved so that the semiconductor device 110 contacts the adhesive layer 300. If the adhesive layer 300 has a glass transition temperature T_{g}, the relationship between the first temperature T₁ and the glass transition temperature T_{g} of the adhesive layer 300 satisfies the equation (1):

$$0 < \frac{{T}_{1} - {T}_{g}}{{T}_{g}} \leq 70 \% \qquad ( 1 )$$

wherein T₁ is the first temperature, and T_{g} is the glass transition temperature.

By applying the first temperature T₁ that satisfies the equation (1) to the adhesive layer 300, the adhesive layer 300 which is cross-linked and cured can be softened, and a greater adhesive force can be generated to the semiconductor device 110. For example, a flat metal with an area of 3×3 mm² is brought into contact with the adhesive layer 300 after the adhesive layer 300 is heated to the first temperature T₁. After the adhesive layer 300 is cooled to room temperature (25° C.), the force to separate the flat metal and the adhesive layer 300 is greater than 500 grams. That is, before the adhesive layer 300 is heated to the first temperature T₁, the adhesive layer 300 does not have any adhesiveness or only has slight adhesiveness. The adhesiveness of the adhesive layer 300 increases after the adhesive layer 300 is heated to the first temperature T₁. At this time, when the semiconductor device 110 contacts the adhesive layer 300, the semiconductor device 110 can be properly fixed to the adhesive layer 300 without falling off easily. If the first temperature T₁ is lower than the glass transition temperature T_{g} of the adhesive layer 300, not only the adhesive layer 300 cannot be effectively softened, but also the adhesion of the adhesive layer 300 cannot be effectively increased. If the first temperature T₁ is too high and exceeds the upper limit (ie, 70%) of the equation (1), the adhesive layer 300 will soften excessively, causing multiple semiconductor devices 110 are sunk into the adhesive at different depths. As a result, the rear surface 110b of the semiconductor devices 110 are not substantially located at the same elevation, which is not conducive to the subsequent transfer process.

After the semiconductor device 110 is adhered to the adhesive layer 300, the adhesive layer 300 is stopped to be maintained at the first temperature T₁. The temperature of the adhesive layer 300 returns to a predetermined temperature, such as room temperature. When the temperature returns to room temperature, there is still adhesive force between the semiconductor device 110 and the adhesive layer 300, so the semiconductor device 110 can still adhere to the adhesive layer 300.

Next, as shown in FIG. 6, in step S106, the first support substrate 400 and the semiconductor device 110 are separated, and the rear surface 110b of the semiconductor device 110 is exposed. In one embodiment, the first support substrate 400 is a growth substrate, a laser lift-off process can be used to irradiate laser light from the back surface 404 to the front surface 402 of the first support substrate 400 to decompose the semiconductor material (not shown) between the semiconductor device 110 and the first support substrate 400, such as gallium nitride, aluminum nitride, aluminum gallium nitride, or other compound semiconductors material. When the first support substrate 400 is a non-growth substrate, for example, a heat-resistant tape, a blue tape, or other adhesive film, the first support substrate 400 can also be directly peeled off by external force to expose the rear surface 110b of the semiconductor device 110.

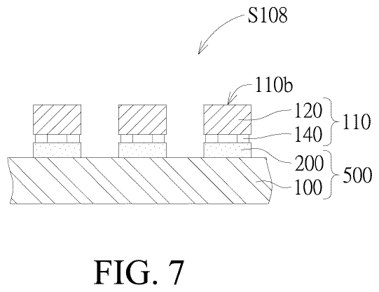

FIG. 7 illustrates a cross-sectional view of an intermediate structure with a patterned adhesive layer 300. As shown in FIG. 7, after step S106 is completed, in step S108, an etching process, such as inductively coupled plasma (ICP) etching, is performed to etch the adhesive layer 300 that is not shielded by the semiconductor device 110, to form a plurality of adhesive portions 200 (also called adhesive sublayers) separated from each other.

By performing steps S102 to S108 shown in FIGS. 5 to 7, the plurality of semiconductor devices 110 is transferred from the first support substrate 400 to the second support substrate 500. The plurality of semiconductor devices 110 is located on the second support substrate 500 and is separated from each other. In one embodiment, the arrangement of the semiconductor devices 110 on the second support substrate 500 is similar or the same as the arrangement of the semiconductor devices 110 on the first support substrate 400.

In one embodiment, the electrical connection 140 has a contact surface contacting the adhesive portion 200 can be a curved surface or a flat surface, and the contact area between the electrical connection 140 and the adhesive portion 200 can be reduced or unchanged when the etching process in step S108 is performed.

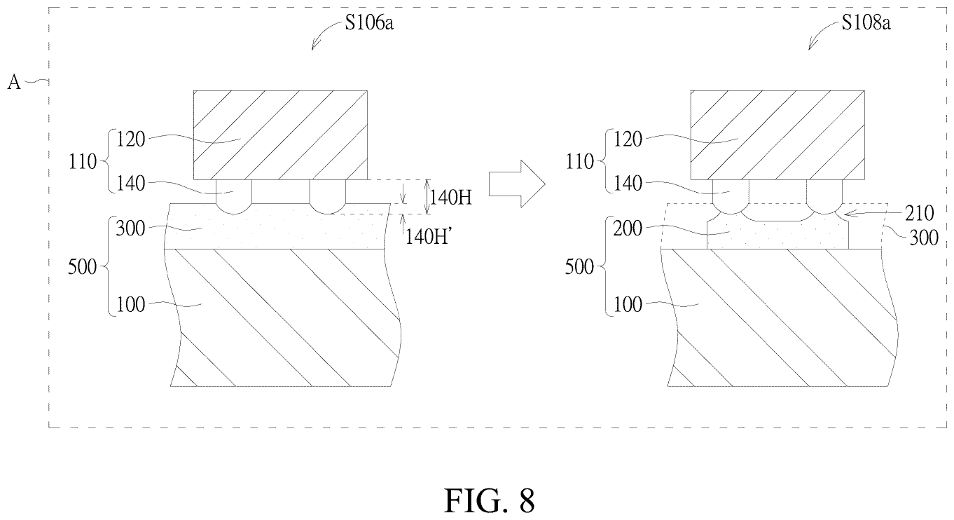

FIG. 8 illustrates a cross-sectional view of a step of patterning the adhesive layer 300 to form the adhesive portion 200 in one embodiment. In FIG. 8, the structure of step S106a is an enlarged view of the area near the electrical connection 140 and the adhesive layer 300 in step S106 in FIG. 6, and the structure of step S108a is an enlarged view of the area near the electrical connection 140 and the adhesive portion 200 in step S108 in FIG. 7.

As shown in step flow A of FIG. 8, in step S106a, the electrical connection 140 includes an arc-shaped bottom surface, and a portion of the electrical connection 140 (for example, part or all of the arc-shaped bottom surface) is embedded into the adhesive layer 300. The portion of the electrical connection 140 embedded into the adhesive layer has a depth 140H′ less than ⅕ of the height 140H of the electrical connection 140. In step S108a, the adhesive layer 300 is etched to form a plurality of adhesive portions 200 which is separated from each other. The adhesive portion 200 includes a protruding portion 210 that contacts the electrical connection 140. In step S108a, the contact area between the adhesive layer 300 and the semiconductor device 110 or between the adhesive portion 200 and the semiconductor device 110 is reduced. The contact area between the adhesive portion 200 and the electrical connection 140 can be adjusted by adjusting parameters of the etching process such as etching time, compositions and/or concentrations of the etchant (including gas or liquid), and temperature of the etchant. Therefore, the adhesive force between the semiconductor device 110 and the adhesive portion 200 can be adjusted to facilitate the subsequent transfer process of the semiconductor device 110.

In one embodiment, the adhesive layer 300 is etched to form a continuous adhesive portion 200 (not shown), that is, two adjacent semiconductor devices 110 are adhered to one adhesive layer 300. The adhesive layer 300 includes two or more protruding portions 210, and the two or more protruding portions 210 respectively connect two adjacent semiconductor devices. The etching process includes isotropic etching and/or anisotropic etching. Isotropic etching includes microwave plasma etching, and anisotropic etching includes inductively coupled plasma (ICP) etching and reactive-ion etching (RIE).

After step S108, a selected semiconductor device 110 on the second support substrate 500 can be transferred to other support substrate (also called target substrate) through a selective transfer process to group the semiconductor devices 110 having the same or similar properties (for example, electrical or optical properties).

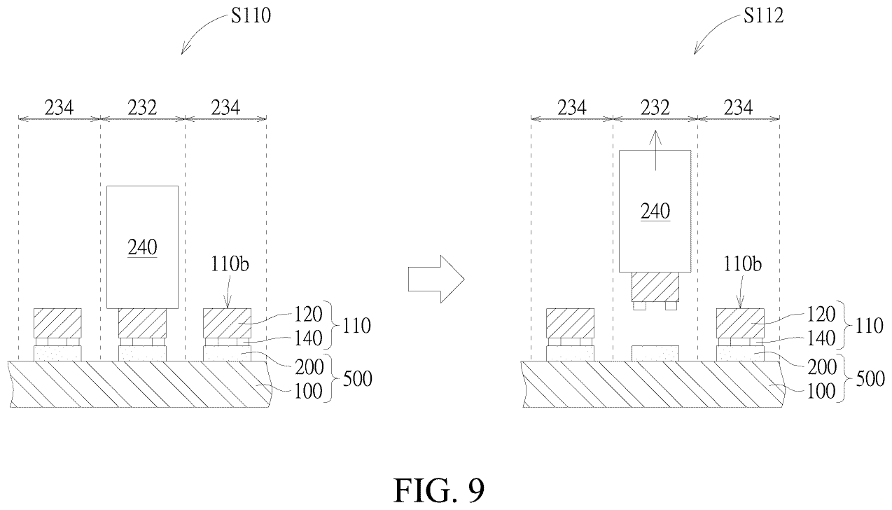

FIG. 9 illustrates a schematic diagram of some intermediate structures in a process of selectively transferring the selected semiconductor device 110 on the second support substrate 500 according to one embodiment. As shown in FIG. 9, in step S110, the semiconductor devices 110 are located in the selected area 232 or the unselected area 234. The semiconductor devices 110 in the selected area 232 are transferred to another support substrate, while the semiconductor devices 110 in the unselected area 234 remain on the second support substrate 500.

In step S110, a pickup device 240 is used to contact the semiconductor device 110 located in the selected area 232. The pickup device 240 adheres the semiconductor device 110 by electrostatic force, adhesive force, magnetic force or vacuum adsorption force. In step S112, the pickup device 240 is lifted so that the semiconductor device 110 is detached from the adhesive portion 200, no adhesive portion 200 or only an acceptable amount of adhesive portion 200 remains on the electrical connection 140 of the semiconductor device 110.

In subsequent processes, other semiconductor devices 110 located in the unselected area 234 can be transferred from the second support substrate 500 to other support substrates or target substrates. The transfer process can be repeated until all semiconductor devices 110 located on the second support substrate 500 are transferred to the same and/or different support substrates or target substrates.

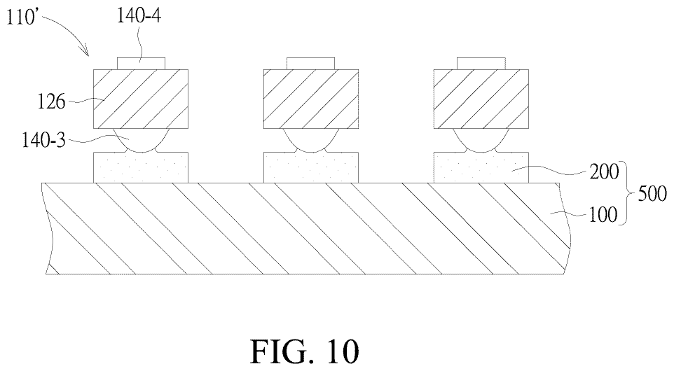

As shown in FIG. 10, in one embodiment, a plurality of vertical semiconductor devices 110′ are located on the second support substrate 500 and separated from each other. A first electrical connection 140-3 and a second electrical connection 140-4 of the vertical semiconductor device 110′ are located on opposite sides of the semiconductor stack 126, and the first electrical connection 140-3 contacts the adhesive portion 200. The structure and material of the first electrical connection 140-3 can be referred to the first electrical connection 140-1 of the semiconductor device 110 in FIG. 3 and related paragraphs.

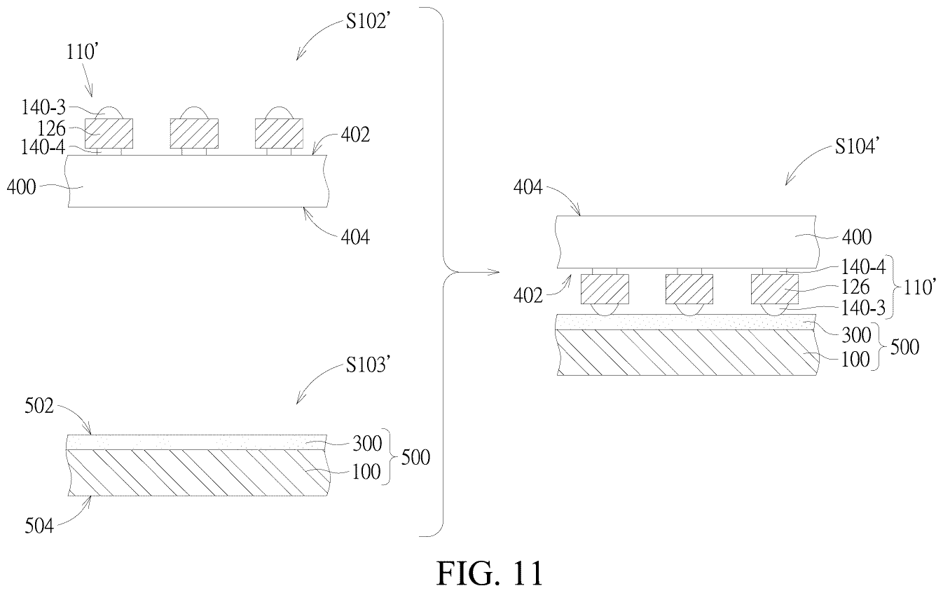

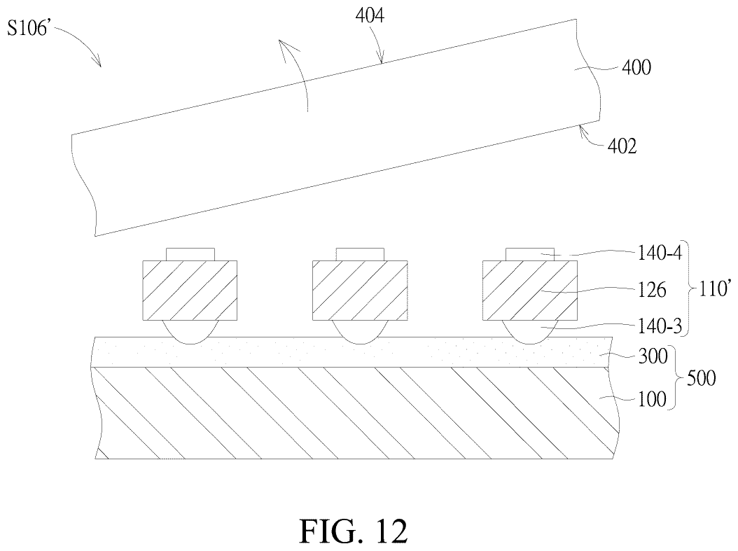

FIG. 11 illustrates a cross-sectional view of some intermediate structures in a process of bonding a plurality of vertical semiconductor devices 110′ to a second support substrate 500 according to one embodiment. In one embodiment, the vertical semiconductor device 110′ is a transistor or a LED, and the vertical semiconductor device 110′ includes the first electrical connection 140-3 and the second electrical connection 140-4 located on opposite sides of semiconductor stack 126. FIG. 12 illustrates a cross-sectional view of an intermediate structure during a process of separating the first support substrate 400 and the vertical semiconductor device 110′ in one embodiment. As shown in FIG. 11, in step S102′, a plurality of vertical semiconductor devices 110′ are provided on the front surface 402 of the first support substrate 400. The first electrical connection 140-3 of the vertical semiconductor device 110′ is farther away from the first support substrate 400 than the second electrical connection 140-4. A connection layer (not shown) can be disposed between the second electrical connection 140-4 and the front surface 402 of the first support substrate 400 to temporarily fix the vertical semiconductor devices 110′ on the first support substrate 400, wherein the connection layer includes polymer. In one embodiment, the connection layer directly contacts the semiconductor stack 126, and the second electrical connection 140-4 is completely embedded into the connection layer. In one embodiment, the second electrical connection 140-4 is not completely embedded into the connection layer, and the connection layer is not in direct contact with the semiconductor stack 126. In one embodiment, the first electrical connection 140-3 includes an n-type conductive bump with a curved surface, and the second electrical connection 140-4 includes a p-type conductive pad with a flat surface. The detailed structure of the vertical semiconductor device 110′ can be referred to FIG. 10 and related descriptions.

As shown in FIG. 11, in step S103′, the second support substrate 500 is provided. The second support substrate 500 has a front side 502 and a back side 504 opposite to the front side 502, and includes a carrier 100 and an adhesive layer 300 continuously distributed on the carrier 100. The adhesive layer 300 is disposed on the front side 502 of the carrier 100, and the thickness of the adhesive layer 300 is in the range of 0.05 μm to 5 μm. In one embodiment, the adhesive layer 300 includes a polymer with a glass transition temperature T_{g}, such as about 120° C., and the polymer is cured in step S103′. In step S103′, the adhesive layer 300 does not have any adhesiveness. The materials and details of the first support substrate 400, the adhesive layer 300, and the second support substrate 500 can be referred to FIG. 5 and related paragraphs.

As shown in FIG. 11, in step S104′, the adhesive layer 300 is heated to a first temperature T₁ (for example, about 130° C.), and at least one of the first support substrate 400 and the second support substrate is moved, so that the first electrical connection 140-3 of the vertical semiconductor device 110′ contacts the adhesive layer 300. The relationship between the first temperature T₁ and the glass transition temperature T_{g} of the adhesive layer 300 satisfies the equation (1) in the previous paragraph. In step S104′, when the vertical semiconductor device 110′ contacts the adhesive layer 300, the vertical semiconductor device 110′ can be well fixed on the adhesive layer 300. After the vertical semiconductor device 110′ is adhered to the adhesive layer 300, the adhesive layer 300 is stopped to be maintained at the first temperature T₁, so that the temperature of the adhesive layer 300 falls back to a predetermined temperature, such as room temperature. When the temperature returns to room temperature, there is still adhesion between the vertical semiconductor device 110′ and the adhesive layer 300, so the vertical semiconductor device 110′ can still be adhered to the adhesive layer 300.

As shown in FIG. 12, in step S106′, the first support substrate 400 and the vertical semiconductor device 110′ are separated from each other to expose the second electrical connection 140-4 of the vertical semiconductor device 110′. In one embodiment, the first support substrate 400 and the vertical semiconductor device 110′ are separated by a mechanical force or a laser lift-off process.

As shown in FIG. 11, the first electrical connection 140-3 of the vertical semiconductor device 110′ contacts the adhesive layer 300 through the bonding process in step S104′, and a portion of the first electrical connection 140-3 is embedded into the adhesive layer 300. As shown in FIG. 12, in step S106′, after the first support substrate 400 is separated, a portion of the first electrical connection 140-3 is still embedded into the adhesive layer 300.

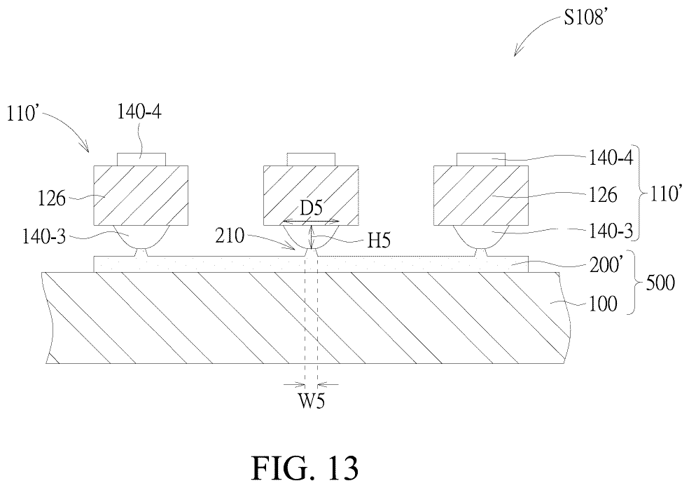

As shown in FIG. 13, in step S108′, an isotropic etching process, such as a microwave plasma etching process, is used to etch the adhesive layer 300 to form a continuous adhesive portion 200′. The adhesive portion 200′ includes a plurality of protruding portion 210. In one embodiment, one protruding portion 210 is connected to one first electrical connection 140-3. In one embodiment, the adhesive layer 300 is etched through anisotropic etching process, such as ICP, to form the adhesive portion 200′. In one embodiment, as shown in FIG. 10, the adhesive layer 300 is formed into a plurality of adhesive portions 200 separated from each other.

In one embodiment, the contact area between the first electrical connection 140-3 and the protruding portion 210 is smaller when the curvature radius of the first electrical connection 140-3 is smaller. In one embodiment, the smaller the curvature radius of the first electrical connection 140-3 is, the smaller the width W5 of the protruding portion 210 is. As shown in FIG. 13, in one embodiment, the ratio (H5/D5) of the height H5 to the diameter (or length, width) D5 of the first electrical connection 140-3 is greater than or equal to 0.5, wherein the height H5 is, for example, about 3.2 μm, and the diameter D5 is, for example, about 6.5 μm. The width W5 of the protruding portion 210 is equal to or less than 1.35 μm.

As shown in FIG. 13, after step S108′, the selected vertical semiconductor device 110′ on the second support substrate 500 can be transferred to other support substrate (also called target substrate) through a selective transfer process to group the vertical semiconductor devices 110′ having the same or similar properties (for example, electrical or optical properties).

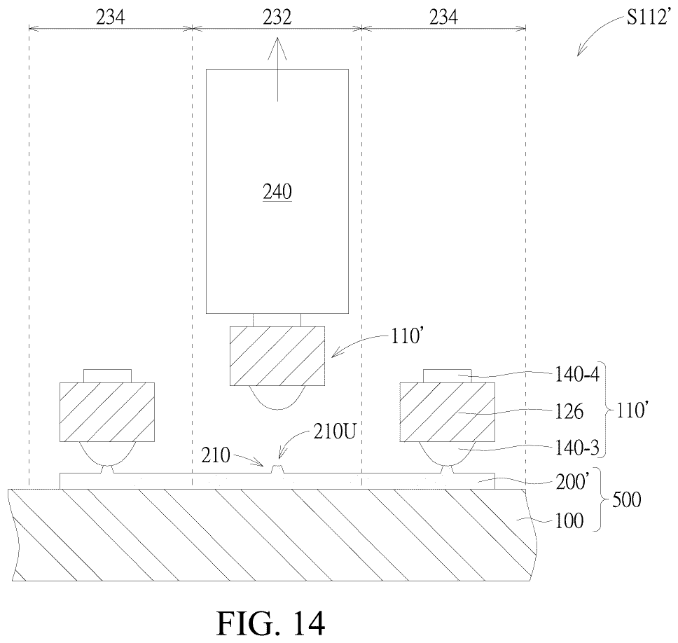

FIG. 14 illustrates a cross-sectional view of a step using a pickup device 240 to transfer a selected vertical semiconductor device 100′ on a second support substrate 500. The plurality of vertical semiconductor devices 110′ are located in the selected area 232 and the unselected area 234. The vertical semiconductor device 110′ in the selected area 232 is transferred to another support substrate, and the vertical semiconductor devices 110′ in the unselected area 234 remain on the second support substrate 500.

In step S112′, the pickup device 240 contacts the vertical semiconductor device 100′ located in the selected area 232 and adheres the vertical semiconductor device 110′ by electrostatic force, adhesive force, magnetic force or vacuum adsorption force. Then, the pickup device 240 is lifted so that the vertical semiconductor device 110′ is detached from the protruding portion 210 of the adhesive portion 200′. No adhesive portion 200′ or only an acceptable amount of adhesive portion 200′ remains on the first electrical connection 140-3 of the vertical semiconductor device 110′. As shown in FIG. 14, in one embodiment, all or part of the protruding portion 210 still remains on the second support substrate 500 after the vertical semiconductor device 110′ is separated from the adhesive portion 200′, and is not completely broken and separated from the adhesive portion 200′ with the vertical semiconductor device 110′.

Although some embodiments of the present disclosure and their advantages have been described in detail, various changes, substitutions and alterations may be made herein without departing from the spirit and scope of the disclosure as defined by the appended claims.

What is claimed is:

1. A semiconductor device arrangement, comprising:
a carrier;
a plurality of semiconductor devices located on the carrier, and comprising a first semiconductor device, wherein, the first semiconductor device comprises a semiconductor stack, a first electrode, a second electrode, a first electrical connection, and a second electrical connection, the first electrode is located between the semiconductor stack and the first electrical connection, and the first electrical connection and the second electrical connection are arranged to face the carrier; and
a plurality of adhesive portions located between the plurality of semiconductor devices and the carrier, and comprising a first adhesive portion, wherein, the first adhesive portion comprises a first protruding portion connected to the first electrical connection, and a second protruding portion connected to the second electrical connection;
wherein, the first electrical connection and the second electrical connection have uppermost surfaces located at different elevations, and at least one of the first electrical connection and the second electrical connection is located below the semiconductor stack.

2. The semiconductor device arrangement according to claim 1, wherein the first electrical connection has a first curved surface contacting the first protruding portion.

3. The semiconductor device arrangement according to claim 2, wherein the second electrical connection has a second curved surface contacting the second protruding portion, and the first curved surface and the second curved surface have different curvature radii.

4. The semiconductor device arrangement according to claim 1, wherein the first adhesive portion has a flat region located between the first protruding portion and the second protruding portion.

5. The semiconductor device arrangement according to claim 4, wherein the first protruding portion has an endpoint farthest from the semiconductor stack, and the flat region has a top surface below the endpoint.

6. The semiconductor device arrangement according to claim 5, wherein the endpoint is surrounded by the first protruding portion.

7. The semiconductor device arrangement according to claim 4, wherein the first protruding portion is integrally formed with the flat region.

8. The semiconductor device arrangement according to claim 1, wherein, in a top view, the first adhesive portion has a maximum width smaller than that of the first semiconductor device.

9. The semiconductor device arrangement according to claim 8, wherein, in the top view, the first semiconductor device completely covers the first adhesive portion.

10. The semiconductor device arrangement according to claim 1, wherein the first protruding portion and the second protruding portion have a height difference smaller than 1 μm.

11. The semiconductor device arrangement according to claim 1, wherein the first protruding portion has a maximum width smaller than that of the first electrical connection.

12. The semiconductor device arrangement according to claim 1, wherein the first protruding portion has a height larger than that of the first electrical connection.

13. A method of manufacturing a semiconductor device arrangement, comprising:
providing a first support substrate and a plurality of semiconductor devices located on the first support substrate;
providing a second support substrate, wherein the second support substrate comprises a carrier and an adhesive layer located on the carrier, the adhesive layer is cured and has a glass transition temperature; and
heating the adhesive layer to a first temperature, and making the adhesive layer to contact the plurality of semiconductor devices, wherein the first temperature and the glass transition temperature satisfy an equation:
$$0 < \frac{{T}_{1} - {T}_{g}}{{T}_{g}} \leq 70 \%$$
wherein T₁ is the first temperature, and T_{g} is the glass transition temperature.

14. The method of claim 13, wherein the plurality of semiconductor devices comprises a first semiconductor device with a first electrical connection, after making the adhesive layer to contact the plurality of semiconductor devices, the first electrical connection has a portion embedded into the adhesive layer.

15. The method of claim 14, wherein the portion has a depth which is smaller than ⅕ height of the first electrical connection.

16. The method of claim 13, wherein the plurality of semiconductor devices comprises a first semiconductor device with a first electrical connection, after making the adhesive layer to contact the plurality of semiconductor devices, the adhesive layer is partially removed to form a first protruding portion connected to the first electrical connection.

17. The method of claim 16, wherein the adhesive layer and the first electrical connection have a contact area which is reduced when the adhesive layer is partially removed.

18. The method of claim 16, wherein the adhesive layer is formed into a plurality of adhesive portions when the adhesive layer is partially removed.

19. The method of claim 18, wherein the plurality of adhesive portions comprises a first adhesive portion, and the first adhesive portion comprises the first protruding portion.

20. The method of claim 16, wherein the first electrical connection has a height larger than that of the first protruding portion.
